(19) United States
(12) Patent Application Publication
(10) Pub. No.: US 2005/0110543 A1
(43) Pub. Date: May 26, 2005

(54) Digital signal transmission circuit and method of designing it

(76) Inventors: Hirokazu Touya, Tokyo (JP); Masashi Ogawa, Tokyo (JP)

Correspondence Address: OSTROLENK FABER GERB & SOFFEN, 1180 AVENUE OF THE AMERICAS, NEW YORK, NY, 100368403, US

(21) Appl. No.: 10/493,778

(22) PCT Filed: Oct. 25, 2002
(86) PCT No.: PCT/JP02/11102

(30) Foreign Application Priority Data
Oct. 25, 2001 (JP) 2001-327259

(51) Int. Cl. H03K 5/01

(52) U.S. Cl. 327/165

(57) ABSTRACT

A digital signal transmission circuit which uses a MOS type LSI (1) or the like having, e.g., an FET (3), and which is so configured that a step waveform produced from a transmission terminal such as an FET output terminal (4) reaches a reception terminal such as an FET input terminal (5) via a signal line. A signal line is added with a resistance component in a distributed manner at part or whole thereof. The resistance component may have set therein in advance a voltage drop due to the transmission loss of a signal line so that the amplitude of a transmission signal is damped at a reception terminal to a specified percentage of that at a transmission terminal. For example, it is preferable that the wire and wire length of a signal line be properly selected to serve as an addition to a resistance component so that a voltage drop is almost equal to ½ the amplitude of a transmission signal.

### TECHNICAL FIELD

The present invention relates to a digital signal transmission circuit which can suppress the delay time and the electromagnetic interference, which is mainly suitable to an MOS (metal oxide semiconductor) type LSI (large scale integrated circuit) having an FET (field effect transistor) and its design method.

### BACKGROUND ART

Recently, the smaller size, low-consumption power, and high performance are required for digital devices in accordance with the development of information technology. Therefore, technological problems to be solved are varied. For example, the improvement for design of wiring is an important object. In particular, the improvement for the signal quality and reduction in delay is increasingly required for a signal line in the LSI and the signal line between the LSIs in the digital signal transmission circuit comprising a semiconductor device, a lead frame, and PCB (printed circuit board) wiring.

Conventionally, it is a mainstream in the LSI field that the delay (that is, RC delay) determined by the product of wiring resistance and wiring capacitance among the wiring delays. For example, the above items on the wiring are described in a so-called roadmap (Semiconductor Technology Roadmap Committee of Japan (STRJ), “Research report on the semiconductor technology trend—Technological guideline for development of semiconductor industry”, Ministry of International Trade and Industry, Research on advanced technology concentration type industry, Electric Industries Association of Japan (EIAJ) in the Heisei 11 fiscal year, on March, Heisei 12 fiscal year) or “The International Technology Roadmap For Semiconductors” (Semiconductor Industry Association (SIA), in 1999) as the information source thereof.

According to the above-mentioned semiconductor roadmap, in order to improve the RC delay, the improvement is executed for low resistance and the low dielectric constant. Further, in the future, in order to reduce the paratrphic effect due to the inductive coupling, the effective shield is necessary by adding an wiring layer or ground line. Specifically, the improvement for the low resistance is performed by switching the aluminum wiring to the copper wiring (which has already been used). In accordance with the change in manufacturing processing, another problem is caused in the new manufacturing processing such as migration. Further, for reduction in wiring capacitance, the low dielectric-constant in the conventional insulating member reaches the limit. Therefore, the approach is tested to prevent the insulating film from being thinner from this level in view of the reduction in thickness of wiring by using the copper wiring. Recently, five, six, or more interconnecting layers are laminated. As the interconnecting layer is in the upper direction, the wiring pitch and the thickness of wiring insulating film are increased. With the feature of the above-mentioned wiring structure, the design is recommended so that the wirings of layers are arranged to minimize the RC delay.

Incidentally, as a technology for designing a general digital signal transmission circuit and a signal wiring (transmission path) in a semiconductor circuit attached thereto and for the basic structure of a transmission system thereof, Japanese Unexamined Patent Application Publication No. 6-216272 and Japanese Unexamined Patent Application Publication No. 7-147352 disclose a semiconductor integrated circuit device, Japanese Unexamined Patent Application Publication No. 9-275145 discloses a semiconductor integrated device, Japanese Unexamined Patent Application Publication No. 10-199983 discloses a semiconductor integrated circuit and its manufacturing method, Japanese Unexamined Patent Application Publication No. 11-3945 discloses a clock tree design method of a semiconductor integrated circuit and its semiconductor integrated circuit, Japanese Unexamined Patent Application Publication No. 11-67970 discloses an wiring structure of an LSI package, Japanese Unexamined Patent Application Publication No. 2000-174505 discloses an electronic device, and Japanese Unexamined Patent Application Publication No. 2000-353945 discloses a digital signal output circuit.

The method described in the semiconductor roadmap is based on the lumped-constant circuit theory which is established as the application for low frequency, which is considered as the currently-designed and future technology, and is a general LSI design method. However, the FET switching time used for the current digital integrated circuit is substantially 10 ps (pico sec). If the method described in the semiconductor roadmap is applied to the design of a fast switching circuit for handling a high frequency component in a microwave area of tens GHz, the electromagnetic phenomenon, which is actually caused in the signal wiring, is not correctly grasped. Therefore, there is a problem that a design error is increased and thus the high accuracy is not obtained. Specifically, the wavelength of tens GHz corresponds to approximately 1 cm and therefore the lumped-constant circuit theory is not applied when the wiring length of the LSI is substantially 1 mm. Further, in the case of wiring between the LSIs mounted on the PCB, the wiring length is several cm or more and therefore the lumped-constant circuit theory is not applied. A high-frequency signal, which is propagated in an electric circuit in this case, acts in accordance with the electromagnetic theory established by Maxwell in 19 B.C. as well as the frequency. if a clock frequency of a device during the design is tens MHz (megahertz), the LSI used for the device is manufactured in the latest manufacturing process. Thus, the switching time of the FET mounted on the LSI is excessively fast, that is, approximately 10 ps similar to that of the LSI for high-performance device with the clock frequency of hundreds MHz or more.

In the field for designing the PCB, the design is executed in accordance with the distribution-constant circuit theory close to the electromagnetic theory for a relatively long time. In this case, the wiring in the LSI or the lead frame in the LSI is handled as a device having the lumped constant and only the wiring on the PCB is handled as the device having a distribution constant. Actually, the design is not performed based on a systematic theory for the signal wiring between an FET output terminal in one LSI mounted on the PCB and an FET input terminal in another LSI mounted on the same PCB. Specifically, in the case of the signal wiring between a plurality of FETs arranged in a MOS-type LSI, a technology for a serial terminal is well known, by which a resistor with the same value as that of characteristic impedance on a line is inserted into the FET output terminal serially to the line in accordance with the distribution system circuit theory close to the electromagnetic theory. This technology can be applied if the characteristic impedance of the line between the transmission terminal and the reception terminal is the same over all the lines. In the LSI, semiconductor package, and PCB forming a digital device with high-density mounting, the design is not performed so as to satisfy the above conditions. If the characteristic impedance of the line between the transmission terminal and the reception terminal is the same over all the lines, an wiring layer or ground line needs to be added to maintain the continuousness of the line cross-sectional structure in the LSI in accordance with the technical element expected by the semiconductor roadmap. Thus, the complicated matching terminal needs to be formed, including the parallel resistance every discontinuous point in the line cross-sectional structure. In order to satisfy the condition, not only the number of wirings and the number of devices in the LSI are excessively increased but also the power consumption is increased. The problems are solved by simply shaping a step waveform for propagating the signal wiring in the digital signal transmission circuit. However, the countermeasure against the problems is currently difficult.

It is one object of the present invention to provide a design method of a digital signal transmission circuit for simply shaping the step waveform which reaches a reception terminal via a signal wiring from a transmission terminal therein.

It is another object of the present invention to provide a digital signal transmission circuit which improves the quality of a transmission signal at the reception terminal of the signal wiring by optically designing the transmission loss of signal wiring and by controlling, to a predetermined value, a falling voltage due to an attenuating constant.

It is further another object of the present invention to provide a digital signal transmission circuit which can effectively suppress the signal distortion at an input gate terminal of a transistor, which is used as the transmitting terminal and the receiving terminal.

### DISCLOSURE OF INVENTION

According to one aspect of the present invention, there is provided a design method of a digital signal transmission circuit which can shape a step waveform generated from a transmission terminal thereof, at a reception terminal, by an attenuating constant obtained by adding a resistance component in a distributed manner to a part of or the entire signal wiring in the case of designing the digital signal transmission circuit with the structure in which the step waveform reaches the reception terminal via the signal wiring.

According to another aspect of the present invention, there is provided a digital signal transmission circuit which can shape a step waveform generated from a transmission terminal thereof, at a reception terminal, by an attenuating constant obtained by adding a resistance component in a distributed manner to a part of or the entire signal wiring in the case of designing the digital signal transmission circuit with the structure in which the step waveform reaches the reception terminal via the signal wiring.

According to another aspect of the present invention, there is provided a digital signal transmission circuit, in which a falling voltage due to the transmission loss of a signal wiring is preset so that an amplitude of a transmission signal having a step waveform supplied to a transmission terminal is attenuated to a predetermined percentage at a reception terminal, as compared with at a transmission terminal, in the digital signal transmission circuit which transmits the transmission signal to the reception terminal via the signal wiring.

### BRIEF DESCRIPTION OF THE DRAWINGS

FIG. 1 is an explanatory diagram of the basic structure of a digital signal transmission circuit according to the first embodiment of the present invention;

FIG. 2 is a diagram showing the voltage change on a signal wiring of the digital signal transmission circuit shown in FIG. 1;

FIGS. 3A to 3C show the schematic structure of a main portion of the digital signal transmission circuit shown in FIG. 1, FIG. 3A is a cross-sectional view showing the fine wiring in an LSI, FIG. 3B is a cross-sectional view showing an wiring of a lead frame with a high dielectric-constant of an LSI package, and FIG. 3C is a cross-sectional view showing an wiring with the high dielectric-constant for PCB;

FIG. 4 is an enlarged cross-sectional view of the fine wiring in the LSI shown in FIG. 3A;

FIG. 5 is a schematic equivalent circuit diagram for SPICE (Simulation Program with Integrated Circuit Emphasis) analysis used for the verification of the digital signal transmission circuit shown in FIG. 1;

FIGS. 6A to 6D show simulation results of the digital signal transmission circuit shown in FIG. 1, FIG. 6A is a voltage waveform diagram at an output terminal of a transistor in the schematic equivalent circuit for SPICE analysis, FIG. 6B is a voltage waveform diagram at an input terminal of the transistor in the schematic equivalent circuit for SPICE analysis, FIG. 6C is a voltage waveform diagram at an input terminal of an wiring for PCB with the high dielectric-constant, FIG. 6D is a voltage waveform diagram at an output terminal of the wiring for PCB with the high dielectric-constant;

FIG. 7 is an explanatory diagram of the basic structure of a digital signal transmission circuit according to the second embodiment of the present invention;

FIG. 8 is a diagram showing the voltage change on a signal wiring in the digital signal transmission circuit shown in FIG. 7;

FIG. 9 is a schematic equivalent circuit for analyzing the SPICE used for the verification of the digital signal transmission circuit shown in FIG. 7;

FIGS. 10A and 10B show the simulation results of the digital signal transmission circuit shown in FIG. 7, FIG. 10A is a voltage waveform diagram at an output terminal of a transistor in the schematic equivalent circuit for analyzing the SPICE, and FIG. 10B is a voltage waveform diagram at an input terminal of the transistor in the schematic equivalent circuit for analyzing the SPICE;

FIG. 11 is an explanatory diagram of the basic structure of a digital signal transmission circuit according to the third embodiment of the present invention; and

FIG. 12 is an explanatory diagram of the basic structure of a digital signal transmission circuit according to the fourth embodiment of the present invention.

### BEST MODE FOR CARRYING OUT THE INVENTION

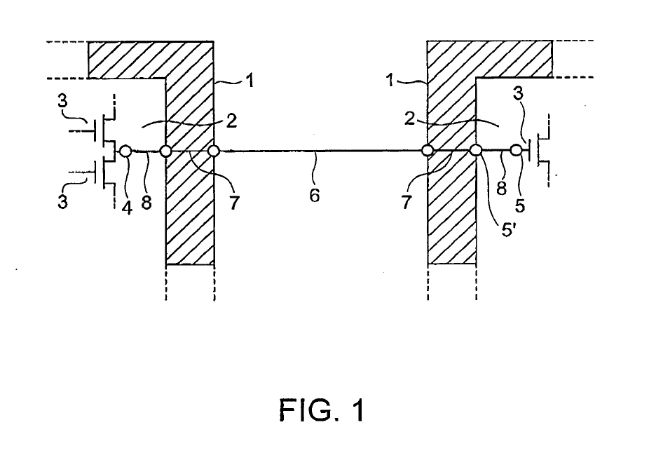

A description is given of a digital signal transmission circuit and its design method according to the first embodiment of the present invention with reference to FIGS. 1 to 4.

Referring to FIG. 1, a digital signal transmission circuit comprises two MOS-type LSIs 1 mounted on a PCB (not shown). Each of the MOS-type LSIs 1 comprises an LSI chip 2 having an FET 3. A signal wiring is connected to a transmit a transmission signal between an FET output terminal 4 and an FET input terminal 5 in the two MOS-type LSIs 1. The signal wiring comprises a line 6 for PCB with a high dielectric-constant on the PCB, two lines 7 for lead frame with the high dielectric-constant as lead frames of the MOS-type LSIs 1, and two fine lines 8 in the LSI arranged in the MOS-type LSIs 1. Here, the cross-sectional area of the fine lines 8 in the LSI is smaller than the those of the line 6 for PCB with the high dielectric-constant and the lines 7 for lead frame with the high dielectric-constant by several digits, and resistance R per unit length of the fine lines 8 in the LSI is much larger than those of the line 6 for PCB with the high dielectric-constant and the lines 7 for lead frame with the high dielectric-constant. IN other words, the line 6 for PCB with the high dielectric-constant and the lines 7 for lead frame with the high dielectric-constant become wirings with low transmission-loss and high dielectric-constant. Therefore, the transmission loss in the digital signal transmission circuit due to the fine lines 8 in the LSI is dominant. The voltage is not fallen due to the transmission loss of the line 6 for PCB with the high dielectric-constant and the lines 7 for lead frame with the high dielectric-constant. The two fine lines 8 in the LSI are designed by selecting the wire material and the wire length so that the falling voltage due to the transmission loss is substantially equal to (2−√2)/2 of an amplitude of a transmission signal at the output terminals 4 and 5′.

The total falling voltage is obtained by summing the falling voltage due to the transmission loss of the two fine lines 8 in the LSI, that due to the transmission loss of the two lines 7 for lead frame with the high dielectric-constant, and that due to the line 6 for PCB with the high dielectric-constant. In the case of the digital signal transmission circuit which is formed by mounting a plurality of MOS-type LSIs on the PCB, the wire material and the wire length of the signal wiring are selected and designed so that the total falling voltage is equal to ½ of the amplitude of the transmission signal. Consequently, the signal distortion is suppressed at the input gate terminal of the FET 3 by using the transmission loss of the conductor of the signal wiring. Therefore, a fast signal can be propagated by only the delay of the dielectric having the resistance component which is added in a distributed manner to a part of or the entire signal wiring.

The above-mentioned design uses the wiring loss in order to shape the signal. Therefore, the above design is similar to the serial connection, to the FET output terminal 4, of matching resistance having the same value as that of the wiring impedance, or to the parallel connection, to the FET input terminal 5, of the matching resistance having the same value as that of the wiring impedance.

The digital signal transmission circuit according to the first embodiment has the advantage that the addition of wiring layer and ground line, which is expected to be necessary in the semiconductor roadmap in the future, is not necessary because the characteristic impedance is not strictly designed for the wiring, unlike the impedance matching at the terminal of a transmission line. The signal is propagated based on the electromagnetic theory, and the signal transmission ends when the wave motion in an electromagnetic transient state reaches the output terminal. Therefore, the wiring delay time is not influenced by the wiring resistance and depends on only the dielectric constant of an insulator existing around the wiring. For example, a specific inductive capacity is 4, the wiring delay time is twice of the propagation time of light.

According to the technology of the well-known semiconductor roadmap, a so-called repeater as a driver circuit is inserted in the wiring, thereby improving the delay time. The delay time in the MOS-type LSIs 1 shown in FIG. 1 is increased by the delay amount of the repeater. In the case of designing the digital signal transmission circuit shown in FIG. 1, the repeater is designed and is used as a buffer for increasing the free degree of the timing design upon selecting the material, shape, and the wire length of the repeater used for the wiring.

Next, a specific description is given of the qualitative principle upon selecting the wiring material and the wiring length of the two fine lines 8 in the LSI so that the line 6 for PCB with the high dielectric-constant and the lines 7 for lead frame with the high dielectric-constant are used and the falling voltage due to the transmission loss is substantially (2−√2)/2 of the amplitudes of the transmission signals, respectively, in the digital signal transmission circuit with reference to FIG. 1.

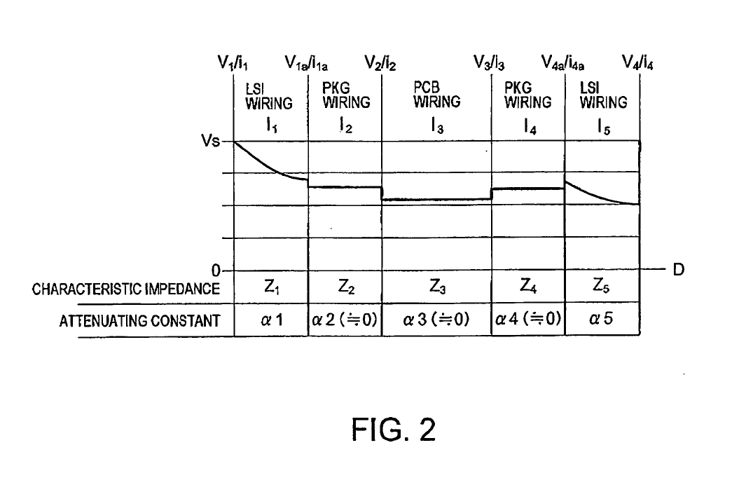

FIG. 2 is a diagram showing the voltage change on the signal wiring in the process in which a step voltage V_{S} is applied to the signal wiring from the FET output terminal 4 in one of the MOS-type LSIs 1 in the digital signal transmission circuit shown in FIG. 1, it reaches the FET input terminal 5 in the other MOS-type LSI 1 via the PCB, and the total reflection is caused because of the opening terminal (the signal route is shown by an axis D of abscissa). Referring to FIG. 2, the step voltage V_{S} applied to the signal wiring from the FET output terminal 4 drops to substantially (2−√2)/2 of the amplitude of the transmission signal in a (fine LSI) wiring 11 portion having a large attenuating constant α₁. That is, the voltage is attenuated to substantially √2/2.

As mentioned with reference to FIG. 1, a PKG wiring I₂ portion of the lead frame has the wiring cross-sectional area larger that that of the LSI wiring I₁ portion by several digits, and the transmission loss does not exist. An attenuating constant α₂ in this case is ignored. However, characteristic impedance exists between the LSI wiring I₁ portion and the PKG wiring I₂ portion. Characteristic impedance Z₂ of the PKG wiring I₂ portion is slightly lower than a characteristic impedance Z₁ of the LSI wiring I₁ portion. The reflection is caused at the connection point and then the voltage applied to the PKG wiring I₂ portion is slightly low.

Further, characteristic impedance Z₃ of a PCB wiring I₃ portion at the PCB wiring portion is generally lower than the characteristic impedance Z₂ of the PKG wiring I₂ portion. Therefore, the reflection is caused at the connection point and the voltage applied to the PCB wiring I₃ portion is further low. As mentioned with reference to FIG. 1, the wiring cross-sectional area of the PCB wiring I₃ portion is wider than that of the LSI wiring I₁ portion by several digits, and the transmission loss does not exist. Therefore, an attenuating constant α₃ is ignored and the falling voltage is actually zero at the PCB wiring I₃ portion.

For the purpose of a brief description, it is assumed that the entire LSIs are manufactured based on the same design spirit. In this case, the electronic characteristic of a PKG wiring I₄ portion in the lead frame portion is substantially the same as that of the PKG wiring I₂ portion. The voltage rises by the reflection at the connection point between the PCB wiring I₃ portion and the PKG wiring I₄ portion. An attenuating constant α₄ is ignored and the falling voltage is actually zero at the PKG wiring I₄ portion.

The electric characteristic of a (fine LSI) wiring I₅ portion is substantially the same as that of the LSI wiring I₁ portion. That is, the voltage rises by the reflection at the connection point between the PKG wiring I₄ portion and the LSI wiring I₅ portion, the voltage is fallen, by a high attenuating constant α₅, to substantially √2/2 of the amplitude of the transmission signal in the LSI wiring I₅ portion, and the voltage is attenuated to substantially (2−√2)/2. As a result, the voltage incident on the input terminal of the FET viewed as the opening terminal is V_{S}/2, and the voltage incident on the terminal is equal to a reflection voltage from the terminal in the case of the opening terminal. Therefore, the addition of the incident voltage and the reflection voltage at the terminal is V_{S}.

Upon designing the digital signal transmission circuit, if the electric characteristic of the component at the signal wiring is selected so that the above-described relationship is established, the value of the voltage of the FET input terminal 5 as the opening terminal finally reaches the step voltage V_{S}. Therefore, the transient phenomenon at least at the FET input terminal ends at this timing and, after that, the state enters a electromagnetically still and steady state. Here, the description has been given of the case in which the attenuating constant is high only for the wiring in the LSI. Further, when the attenuating constant is high for the lead frame or PCB, the similar design is possible. In the latter case, the impedance mismatch in the halfway reduces the attenuating time of the reflection waves and therefore the signal can be transmitted with higher quality.

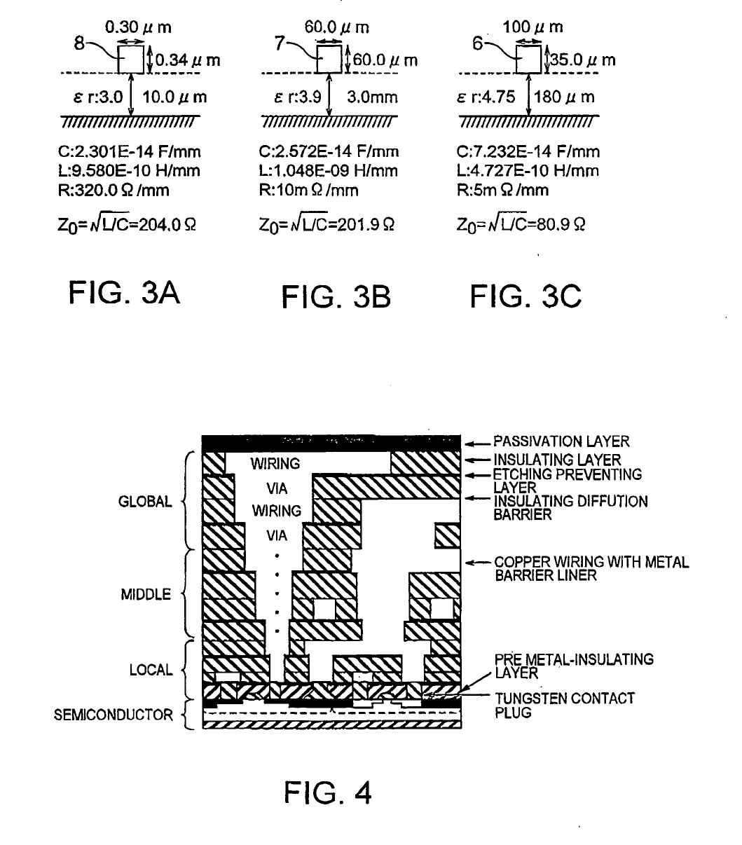

Next, a description is given of the schematic structure of a main portion in the digital signal transmission circuit shown in FIG. 1 with reference to FIGS. 3A to 3C.

The cross-sectional area of a conductive portion in the wiring shown in FIG. 3A is lower than those shown in FIGS. 3B and 3C by several digits, as mentioned above with reference to FIG. 1. Although the resistance R per unit length of the wiring is influenced by the material of the conductive portion of the wiring, it greatly depends on the value of the cross-sectional area of the conductive portion of the wiring. Thus, the resistance R shown in FIG. 3A is excessively higher than the resistance R shown in FIGS. 3B and 3C. Therefore, the transmission loss in the digital signal transmission circuit due to the fine lines 8 in the LSI is dominant.

Referring to FIG. 3A, the fine lines 8 in the LSI is manufactured under a rule of 0.13 μm. Referring to FIG. 4, the actual detailed structure of the LSI wiring has substantially 5 layers, a via hole exists for connecting the layers. The thickness of the wiring portion has a value of several decimal places μm to several numbers μm, and is lower than the thickness of 10 μm to the layer (well layer and a ground layer in this case) with the low dielectric-constant on which the FET is formed. Therefore, the cross section of the schematic structure is shown in FIG. 3A for the purpose of visually easy understanding.

Capacitance C and inductance L per unit length of the fine lines 8 in the LSI are obtained by electromagnetic analysis, and the capacitance C is 2.301E -14 F/mm and the inductance L is 9.580E-10 H/mm. The characteristic impedance Z₀ (=√L/C) is 204.0 Ω, and the resistance R per unit length is 320.0 Ω/mm in the case of using the Aluminum wiring. In any of the wirings shown in FIG. 3A, an insulating material exists between the wiring and the ground surface, and has the specific inductive capacity of 3 in this case.

Referring to FIG. 3B, the capacitance C and inductance L per unit length of the lines 7 for lead frame with the high dielectric-constant in the LSI are obtained by the electromagnetic analysis, and the capacitance C is 2.572E-14 F/mm and the inductance L is 1.048E-09 H/mm. The characteristic impedance Z₀ (=√L/C) is 201.9 Ω, and the resistance R per unit length is 10.0 mΩ/mm in the case of using the Aluminum wiring. In any of the wirings shown in FIG. 3A, the insulating material has the specific inductive capacity of 3.9 in this case.

Referring to FIG. 3C, the capacitance C and inductance L per unit length of the line 6 for PCB with the high dielectric-constant are obtained by the electromagnetic analysis, and the capacitance C is 7.232E-14 F/mm and the inductance L is 4.727E-10 H/mm. The characteristic impedance Z₀ (=√L/C) is 80.9 Ω, and the resistance R per unit length is 5 mΩ/mm in the case of using the Aluminum wiring. The insulating material has the specific inductive capacity of 3.9 in this case.

In general, the inductance L, the capacitance C, the resistance R, and an angle frequency ω are given per unit length of the wiring, an attenuating constant of the line is given by the following formula (1).

$$α = \sqrt{\frac{\begin{matrix}[ \sqrt{( {R}^{2} + {ω}^{2} \cdot {L}^{2} ) \cdot ( {G}^{2} + {ω}^{2} \cdot {C}^{2} )} + \\ ( R \cdot G - {ω}^{2} \cdot L \cdot C ) ]\end{matrix}}{2}} \qquad ( 1 )$$

In the formula (1), reference symbol ω denotes the frequency of a reflection angle and is calculated by (ω=2πf) by using a frequency f of reflection voltage. Further, conductance G is actually zero according to the first embodiment.

A relationship of [f=(I₁+I₂)√(L/C)/2 leads the frequency f of the reflection oscillation generated on the wiring with the length corresponding to the sum of the wiring length (=I₁) of the LSI wiring I₁ portion and that (=I₂) of the PKG wiring I₂ portion, which have the same value of the characteristic impedance. A relational formula of [ω=π(I₁+I₂)√L/C is obtained.

A signal power supply voltage of the step voltage V_{S} is 3.3 V. The attenuating constant of the LSI wiring I₁ portion is designated by reference symbol α₁, and the wiring length of the LSI wiring I₁ portion is designated by reference symbol I₁. Then, a voltage V₁ₐ at the terminal of the LSI wiring I₁ portion is expressed by the following formula (2).
V₁ₐ=3.3·e^{-α}^{₁}^{·|}^{₁} (2)

The following formula (3) expresses a voltage V including the reflection waves when the signal of an amplitude V₀ transmitted to the line with the characteristic impedance Z₀.

$$V = {V}_{0} ( 1 + \frac{{Z}_{0} - {Z}_{1}}{{Z}_{0} + {Z}_{1}} ) \qquad ( 3 )$$

The length of the wiring I₁(=I₂) is calculated so as to set the reflection voltage at an amplitude V₄ shown in FIG. 1 to 3.3 V by using the described relations (including the formulae (1) to (3)), thereby obtaining 0.4367 mm. In this case, the wiring resistance is 139.7 Ω.

Next, the verification of the design result of the digital signal transmission circuit shown in FIG. 1 is performed by the SPICE including the description of the commercially-produced transmission line. However, the electromagnetic analysis of the line including the attenuation constant is generally difficult and therefore the resistor is serially inserted in the SPICE in place of using the attenuating constant. Thus, the basic essential of the design is as mentioned above. The wiring constant is determined by the calculation based on the electromagnetic theory. The serial resistance of the fine LSI wiring portion set by the SPICE does not match the determined wiring constant. However, after designing, the serial resistance can be confirmed by the electromagnetic analysis. Here, it is assumed that the value set by the SPICE is correct.

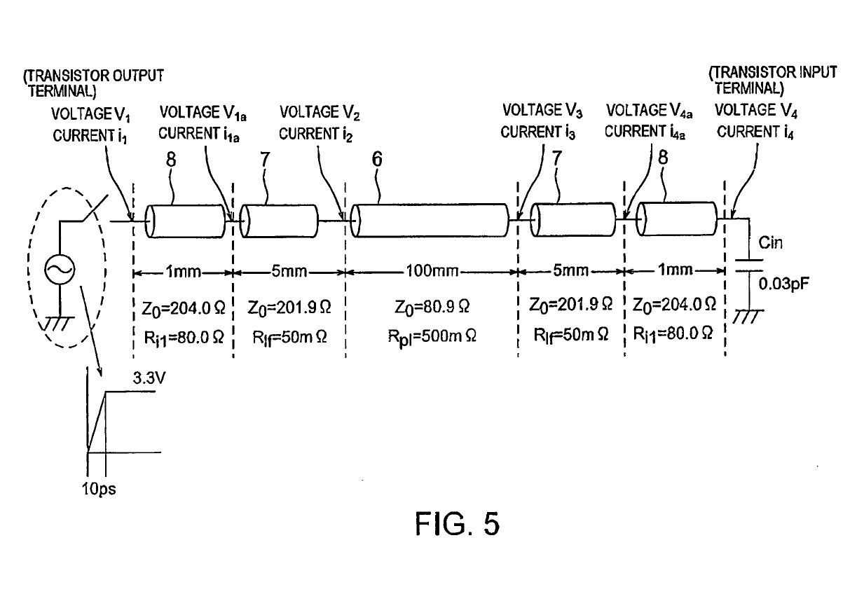

In the case of the SPICE verification, the analysis using the attenuating constant is not performed in the SPICE. Therefore, an equivalent circuit shown in FIG. 5 is used, the wiring length of I₁(=I₂) is 1 mm, and the resistance of I₁(=I₂) as the non-reflection in this case is obtained by repeated simulation. The equivalent circuit comprises the lines 7 for lead frame with the high dielectric-constant between the fine lines 8 in the LSI, and the serial connections are connected between load capacitor Cᵢₙ(=0.03 pF) connected to the ground and the fast constant-voltage power source of 3.3 V which rises at 10 ps and is stable so that the line 6 for PCB with the high dielectric-constant is arranged between the lines 7 for lead frame with the high dielectric-constant. Referring to FIG. 5, the dimension, characteristic impedance, and resistance are shown in the wiring after the voltage and current between the wiring are identified.

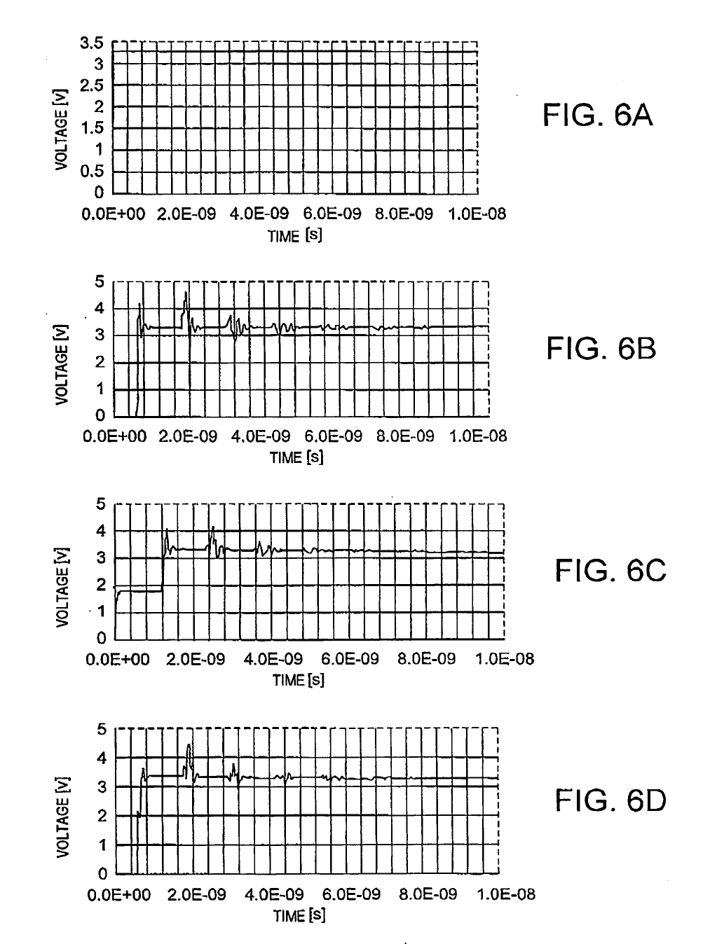

FIGS. 6A to 6D show the waveforms of voltage characteristics in the main portion for the verification of the designing result by the SPICE with the relation of time [s] to voltage [V]. FIG. 6A shows the waveform of a voltage V₁ at an output terminal of the transistor, FIG. 6B shows the waveform of a voltage V₄ at an input terminal of the transistor, FIG. 6C shows the waveform of a voltage V₂ at the input terminal of the line 6 for PCB with the high dielectric-constant, and FIG. 6D shows the waveform of an output voltage V₃ of the line 6 for PCB with the high dielectric-constant.

Referring to FIGS. 6C and 6D, the influence on the reflection appears in the waveform of the input/output voltage in the line 6 for PCB with the high dielectric-constant. Referring to FIG. 6B, the voltage is not changed due to the influence of reflection at the input terminal of the transistor (FET), the waveform disturbance such as the overshoot or undershoot of the signal is suppressed as much as possible, the waveform rises like a step at the delay timing of 0.7 ns. Thus, the attenuating constant directly does not concern to the characteristic impedance of the wiring. That is, the resultant delay of 0.7 ns is substantially ½ of the light speed, the non-dielectric constant of the insulating member of the line is substantially 4 as mentioned above and therefore the delay is only that of the dielectric.

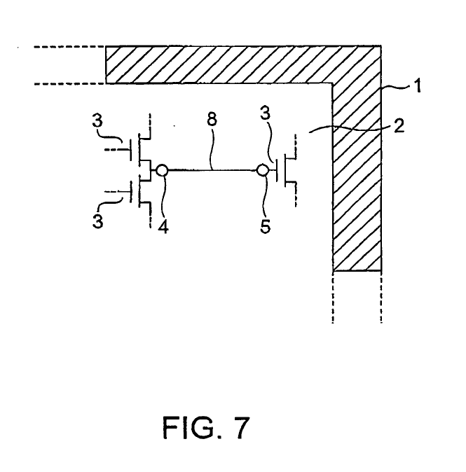

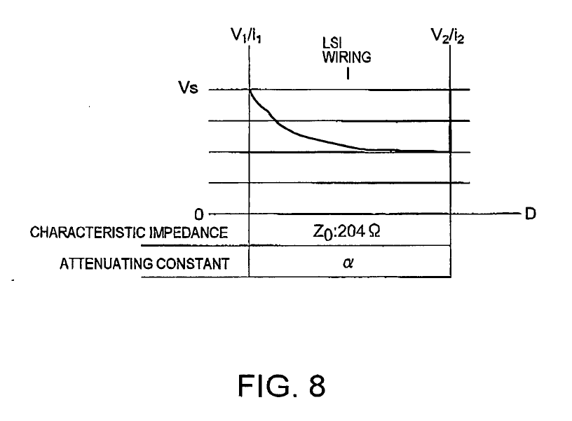

Next, a description is given of a digital signal transmission circuit and its design method according to the second embodiment of the present invention with reference to FIGS. 7 and 8. The same components as those shown in FIGS. 1 and 2 are designated by the same reference numerals, and a description thereof is omitted.

In the digital signal transmission circuit shown in FIG. 7, the one LSI chip 2 comprises the two FETs 3. The FET output terminal 4 of one of the FETs 3 is connected to the FET input terminal 5 of the other FET 3 via the fine lines 8 in the LSI. The fine lines 8 in the LSI has selected wire material, shape, and wire length so that the falling voltage due to the transmission loss is ½ of the amplitude of the transmission signal.

In the above-mentioned design, the loss of the wiring is operated to shape the signal. Therefore, the above design is similar to the serial connection, to the FET output terminal 4, of matching resistance having the same value as that of the wiring impedance, or the parallel connection, to the FET input terminal 5 of the matching resistance having the same value as that of the wiring impedance.

In the digital signal transmission circuit according to the second embodiment of the present invention, the characteristic impedance does not need to strictly be designed for the wiring in the case of designing the impedance matching at the terminal of the transmission line. Therefore, advantageously, the wiring layer and the ground line, which are expected to be necessary in the future in the semiconductor roadmap, are not necessary. In accordance with the electromagnetic theory, the signal is propagated, and the signal transmission ends when the wave motion phenomenon in the electromagnetic transient state appears at the output terminal. Therefore, the wiring delay time is not influenced from the wiring resistance, and depends on only the dielectric constant of the insulating member existing around the wiring. For example, the wiring delay time when the specific inductive capacity is 3 is 1. 7 times of the propagation time of light.

FIG. 8 is a distribution diagram showing the voltage change on the signal wiring in the process in which the step voltage V_{S} is applied to the signal wiring, namely, the fine lines 8 in the LSI, from the FET output terminal 4 in one of the MOS-type LSIs 1 in the digital signal transmission circuit shown in FIG. 7, it reaches the other FET input terminal in the MOS-type LSI 1, the total reflection is caused because of the opening terminal (the signal route is shown by an axis D of abscissa). Referring to FIG. 8, the step voltage V_{S} applied to the signal wiring from the FET output terminal 4 drops to substantially ½ of the amplitude of the transmission signal of the fine lines 8 in the LSI having the attenuating constant α. That is, the voltage is attenuated to substantially ½. As a result, the voltage incident on the input terminal 5 of the FET viewed as the opening terminal is V_{S}/2, and the voltage incident on the terminal is equal to the reflection voltage from the terminal in the case of the opening terminal. Therefore, the addition of the incident voltage and the reflection voltage at the terminal is V_{S}. Upon designing the digital signal transmission circuit shown in FIG. 7, if the electric characteristic of the component at the signal wiring is selected so that the above-described relationship is established, the value of the voltage of the FET input terminal 5 as the opening terminal finally reaches the step voltage V_{S}. Therefore, the transient phenomenon at least at the FET input terminal 5 ends at this timing and, after that, the state enters an electromagnetically still and steady state.

In the digital signal transmission circuit shown in FIG. 7, it is assumed that the insulating member exists between the fine lines 8 in the LSI and the ground surface. The capacitance C and inductance L per unit length of the fine lines 8 in the LSI are obtained by the electromagnetic analysis, and the capacitance C is 2.301 E-14 F/mm and the inductance L is 9.580E-10 H/mm. The characteristic impedance Z₀ (=√L/C) is 204.0 Ω, and the resistance R per unit length is 320.0 mΩ/mm in the case of using the Aluminum wiring. The insulating member has the specific inductive capacity of 3 in this case. The inductance L, the capacitance C, the resistance R, and the angle frequency ω are given per unit length of the wiring, the attenuating constant of the line is given by the above-mentioned formula (1). The conductance G is 0 and then the frequency of the reflection angle ω and the frequency f of the reflected oscillation has the relation of (ω=2πf).

The frequency f of the reflection oscillation generated in the fine lines 8 in the LSI of the wiring length I having the same characteristic impedance is obtained based on the (f=I√(L/C)/2). Thus, a relationship of [ω=π|√L/C] is obtained. Here, the signal power supply voltage of the step voltage V_{S} is 3.3 V. The attenuating constant of the LSI wiring portion is designated by reference symbol α, and the wiring length of the LSI wiring portion is designated by reference symbol I. Then, a voltage V₂ at the terminal of the fine lines 8 in the LSI is expressed by the following formula (4).
V₂=3.3·e^{-α·|} (4)

The length I of the wiring is calculated so as to output the reflection voltage V₂ (=3.3 V) by using the described relational formulae (including the formulae (1) to (4)), thereby obtaining 0.716 mm. In this case, the wiring resistance is 231.626 Ω.

Next, the verification of the design result of the digital signal transmission circuit shown in FIG. 7 is performed by the SPICE including the description of the commercially-produced transmission line. The wiring constant determined by the calculation based on the electromagnetic theory does not match the serial resistance of the fine lines 8 in the LSI set by the SPICE. Therefore, after designing, the serial resistance can be confirmed by the electromagnetic analysis. Here, it is assumed that the value set by the SPICE is correct.

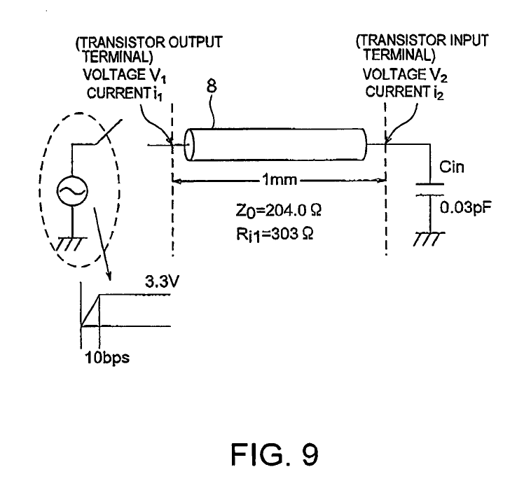

In the case of the SPICE verification, the analysis using the attenuating constant is not performed by using the SPICE. Therefore, an equivalent circuit shown in FIG. 9 is used, the wiring length is 1 mm, and the resistance having the non-reflection in this case is obtained by repeated simulation. The equivalent circuit intervenes and is connected to the fine lines 8 in the LSI between load capacitor Cᵢₙ(=0.03 pF) connected to the ground and the fast constant-voltage power source of 3.3 V which rises at 10 ps and is stable. The dimension, characteristic impedance, and resistance of the wiring are shown after the voltage and current between the wirings are identified.

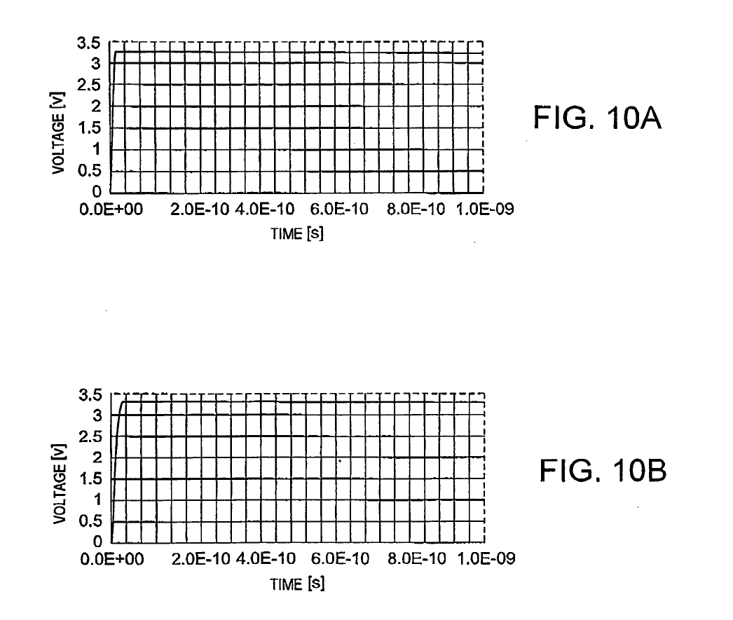

FIGS. 10A and 10B show the waveforms of voltage characteristics in the main portion for the verification of the designing result by the SPICE in the digital signal transmission circuit shown in FIG. 7 with the relation of time [s] to voltage [V]. FIG. 10A shows the waveform of the voltage V₁ at the output terminal of the transistor and FIG. 10B shows the waveform of the voltage V₂ at the input terminal of the transistor.

Referring to FIGS. 10A and 10B, it is confirmed that the reflection at the input terminal of the transistor (FET) does not exist, the waveform disturbance such as the signal overshoot or undershoot is extremely suppressed, and the signal rises like a step by the delay of 10.5 ps. As a result, it is understood that the value of the attenuating constant directly does not relate to the characteristic impedance. The delay of 10.5 ps is the addition of the time for charging the load capacitor Cᵢₙ(=0.03 pF) by the wiring of the characteristic impedance Z₀(=204.0 Ω) and the delay time due to the dielectric when the non-dielectric constant of the insulating material of the line is 3. When the length of wiring in the example is short, that is, 1 mm, the time for charging the load capacitor Cᵢₙ greatly influences the delay and, however, when the wiring is long, it can be ignored.

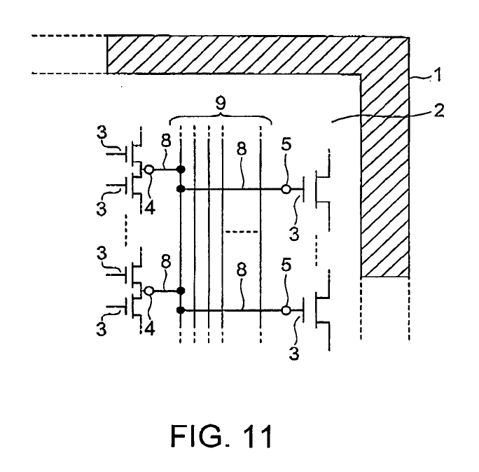

A description is given of a digital signal transmission circuit and its design method according to the third embodiment of the present invention with reference to FIG. 11. The same portion are designated by the same reference numerals and a description thereof is omitted.

In the digital signal transmission circuit shown in FIG. 11, the one LSI chip 2 comprises a plurality of FETs 3. The FETs 3 are connected by using a plurality of signal bus fine wirings 9 as the signal wiring. The signal bus fine wirings 9 have the selected wire material, shape, and wire length so that the falling voltage due to the transmission loss is ½ of the amplitude of the transmission signal. The voltage at the FET input terminal 5 reaches the power voltage as the constant value without vibration, and the basic transient phenomenon ends at this timing.

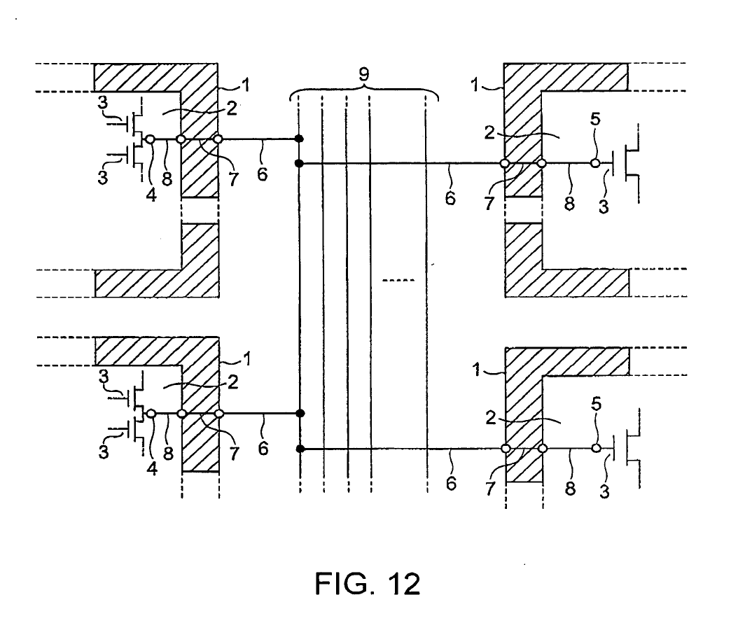

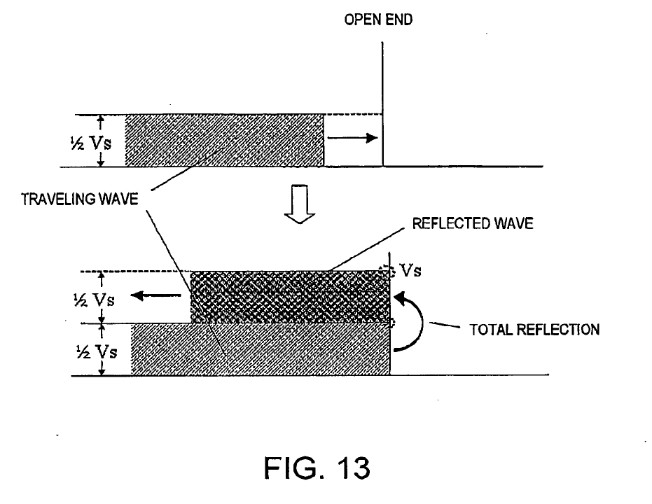

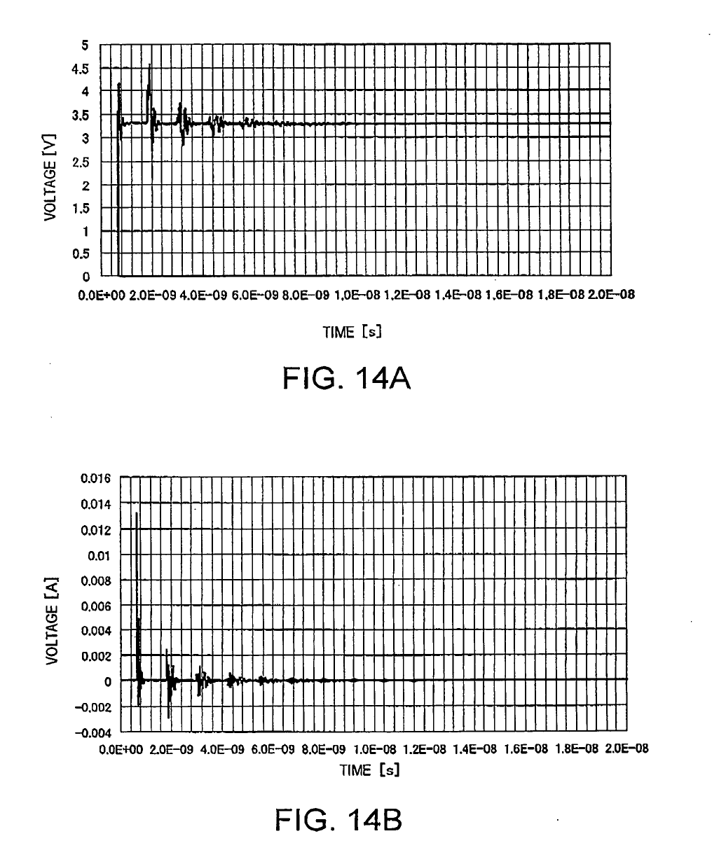

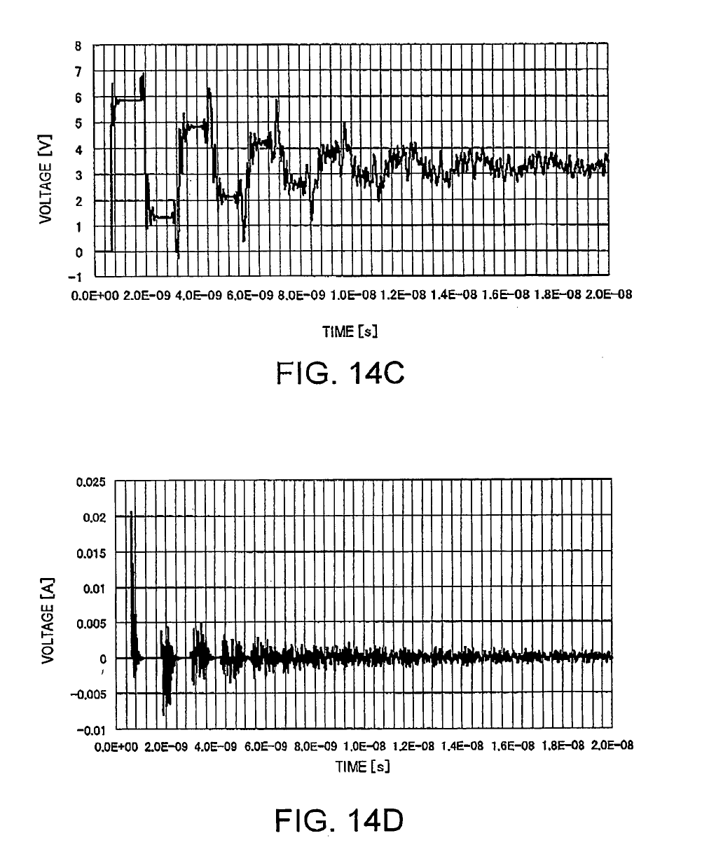

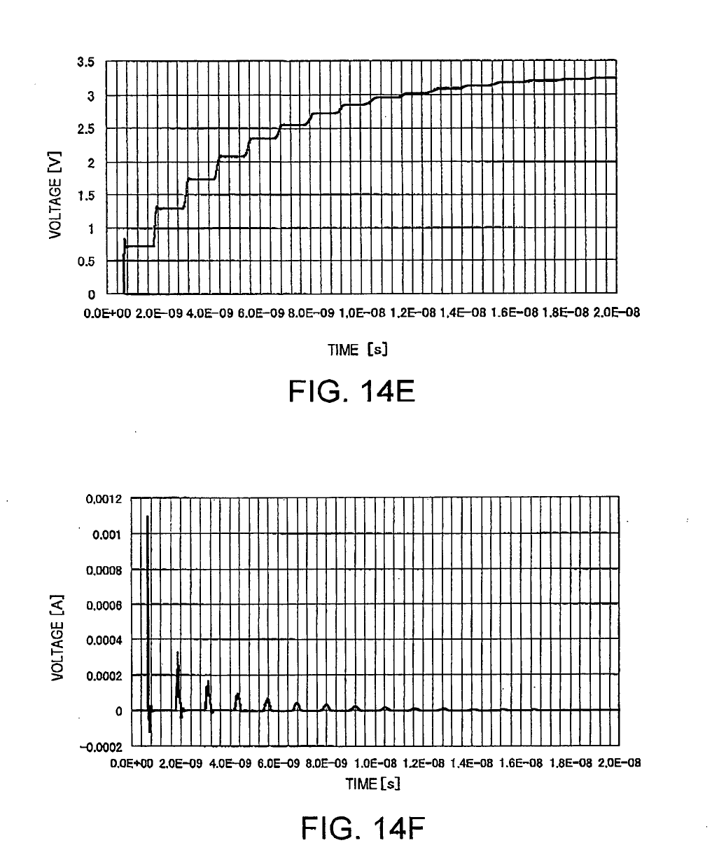

A description is given of a digital signal transmission circuit and its design method according to the fourth embodiment of the present invention with reference to FIG. 12. The same portions are designated by the same reference numerals and a description thereof is omitted.

The digital signal transmission circuit shown in FIG. 12 comprises a plurality of (four in FIG. 12) MOS-type LSIs 1 in which the LSI chips 2 individually store the total four FETs 3 having two pairs of the FET output terminal 4 and the FET input terminal 5 on the PCB. In the digital signal transmission circuit, the signal bus fine wirings 9 are connected as the signal wiring between the FET output terminals 4 and the FET input terminals 5 which face the FETs 3 mounted on the two individual MOS-type LSIs 1.

The wire material and the wire length of the signal bus fine wirings 9 are selected so as to set, to ½ of the amplitude of the transmission signal, the total falling voltage of the falling voltage due to the transmission loss, the falling voltage due to the transmission loss due to the lines 7 for lead frame with the high dielectric-constant in the two individual MOS-type LSIs 1, and the falling voltage due to the transmission loss of the line 6 for PCB with the high dielectric-constant. As another pattern, with the wiring having the low transmission loss and the high dielectric-constant for the read frame and the PCB in the MOS-type LSI, the wire material and the wire length of the fine lines 8 in the two individual LSIs are selected so as to set, to substantially (2−√2)/2 of the amplitude of the transmission signal, the falling voltage due to the transmission loss. The voltage at the FET input terminal 5 reaches the power voltage as the constant value without vibration, and the basic transient phenomenon ends at this timing.

According to the first to fourth embodiments, in the case of designing the digital signal transmission circuit with the structure in which the step waveform generated from the transmission terminal of one LSI therein reaches the reception terminal of another LSI via the signal wiring, the step waveform can be shaped at the reception terminal by the attenuating constant which is obtained by entirely or partly adding the resistance components in a distributed manner. Therefore, in the case of designing the signal wiring, the signal distortion is more efficiently suppressed at the input gate terminal of the transistor used as the transmission terminal and reception terminal by using the transmission loss as the result of the fine manufacturing or high specific electric conductivity of the conductor, as compared with the case in which the complicated transmission line is the matching terminal. Further, the signal with the substantial light-speed can be propagated only by the delay due to the dielectric of the insulating member for adding the resistance component.

The above description has been given of the specific digital signal transmission circuit and its design method. However, the present invention is not limited to this and can variously be modified. For example, as the wire material when the falling voltage in the fine wiring is ½ of the amplitude of the transmission signal, aluminum and copper are preferable. Further, as the wire material when the falling voltage in the fine wiring is (2−√2)/2 of the amplitude of the transmission signal, aluminum, copper, gold, and silver are preferable. The alignment of the wire material in the case of the LSI package has the structure suitable to BGA (ball grid array), FBGA (fine pitch ball grid array), or CSP (chip size package). The PCB can use a laminated copper board, ceramic multi-layer board, or a build-up board with the interlayer via structure and the layer wiring. Further, in the case of designing the signal wiring between the calculating circuits when the digital signal transmission circuit includes a plurality of calculating circuits which operate at the clock frequency, preferably, the signal wirings of the plurality of calculating circuits which operate by the same clock frequency are close thereto and the signal wirings of the calculating circuits with the different clock frequency are physically insulated. Furthermore, in the case of designing a plurality of the signal wiring between the calculating circuits when the digital signal transmission circuit includes a plurality of calculating circuits which operate by the clock frequency, when the wiring length in the single group of the plurality of signal wiring is the same, the wirings from the transmission terminal to the reception terminal of the group which operates by he same clock frequency are close thereto, the timings of the transient phenomenon match upon changing the step waveform, and the electromagnetic interference can be suppressed and the fast processing can be performed.

As mentioned above, according to the present invention, essentially, the impedance of the wiring is optimized in the digital signal transmission circuit. Thus, it is possible to suppress the disturbance of signal waveform which is transiently generated in the signal line, such as overshoot, undershoot, and ringing, to prevent the erroneous operation thereof, and to transmit the signals fast.

The present invention is according to the technology for optimizing the impedance in view of the impedance of the wiring, which is transmitted by the signal without using any additional circuit such as a buffer circuit or clamping circuit. Advantageously, the great increase in number of wirings and in number of devices and the increase in power consumption are suppressed upon transmitting the digital signal fast.

### Industrial Applicability

The digital signal transmission circuit according to the present invention is preferable to a signal circuit system in a calculating processing device such as a PC or server.

1. A digital signal transmission circuit comprising a transmission terminal, which is formed in contact with a dielectric and to which an input signal is applied, and a signal wiring having a reception terminal,
wherein, upon propagating, to the signal wiring and the dielectric, an electric signal and electromagnetic waves generated by the electric signal, an attenuating constant from the transmission terminal to the reception terminal is set so that the waveform distortion at the reception terminal and the waveform interference have an allowable value or less.

2. A digital signal transmission circuit according to claim 1, wherein the attenuating constant is set by referring to the transmission loss which is partly or entirely added to the signal wiring in a distributed manner.

3. A digital signal transmission circuit according to claim 1, wherein the attenuating constant is set so that the amplitude of the electric signal at the reception signal is ½ of the amplitude of the input signal.

4. A digital signal transmission circuit according to claim 3, wherein the transmission terminal comprises an FET output terminal mounted on an LSI, the reception terminal comprises an FET input terminal mounted on the same LSI, and the signal wiring comprises a fine wiring in the LSI.

5. A digital signal transmission circuit according to claim 4, wherein the attenuating constant is calculated by referring to the electric characteristic, shape, and wiring length of the wiring.

6. A digital signal transmission circuit according to claim 4, wherein the signal wiring comprises a bus wiring.

7. A digital signal transmission circuit according to claim 3, wherein the transmission terminal comprises an FET output terminal mounted on a first LSI, the reception terminal comprises an FET input terminal mounted on a second LSI, and the signal wiring comprises a fine wiring in the first and second LSIs, an external terminal forming the first and second LSIs, an wiring for connecting the external terminal and the circuits in the LSIs, and wirings of printed wirings on a printed circuit board.

8. A digital signal transmission circuit according to claim 7, wherein the attenuating constant is calculated by referring to the electric characteristic, shape, and wiring length of the wirings.

9. A digital signal transmission circuit according to claim 7, wherein the signal wiring comprises a bus wiring.

10. A digital signal transmission circuit according to claim 7, wherein, by using the external terminal forming the first and second LSIs, the wiring for connecting the external terminal and the circuits of the LSIs, and an wiring with low transmission-loss and high conductivity for the printed wiring on the printed circuit board, the falling voltage in the fine wirings in the first and second LSIs is (2−√2)/2 of the amplitude of the input signals.

11. A digital signal transmission circuit according to claim 10, wherein the signal wiring comprises a bus wiring.

12. A digital signal transmission circuit according to claim 6, wherein the digital signal transmission circuit includes a plurality of calculating circuits which operate by a clock frequency, in the signal wiring between the calculating circuits, the signal wirings that operate by the same clock frequency are arranged close thereto in the plurality of signal wirings, and the signal wirings that operate by the different clock frequencies are physically isolated.

13. A digital signal transmission circuit according to claim 11, wherein the signal wiring of a plurality of calculating circuits that operate by the same clock frequency comprises a plurality of groups, and the wiring in the same group has the same length.

14. A digital signal transmission circuit according to claim 1, wherein the input signal includes a step waveform.

15. A digital signal transmission circuit according to claim 1, wherein the attenuating constant is set so that the amplitude of the electric signal at the reception terminal is attenuated to a predetermined percentage.

16. A digital signal transmission circuit according to claim 15, wherein the input signal includes a step waveform.

17. (canceled)

18. (canceled)
